(19) United States
(12) Patent Application Publication
(10) Pub. No.: US 2025/0113649 A1
(43) Pub. Date: Apr. 3, 2025

(54) ELECTRONIC DEVICE COMPRISING A SOLAR CELL AND METHOD FOR MANUFACTURING SAID SOLAR CELL

(71) Applicant: THE SWATCH GROUP RESEARCH AND DEVELOPMENT LTD, Marin (CH)

(72) Inventor: Julien BAILAT, Bienne (CH)

(73) Assignee: The Swatch Group Research and Development Ltd., Marin (CH)

(21) Appl. No.: 18/292,160

(22) PCT Filed: May 20, 2022
(86) PCT No.: PCT/EP2022/063792

§ 371 Date: Jan. 25, 2024

(30) Foreign Application Priority Data
Aug. 30, 2021 (EP) 21193822.0

(51) Int. Cl. H01L 21/02; G04C 10/02

(52) U.S. Cl. CPC H10F 77/147; G04C 10/02; H10F 10/17; H10F 71/1385; H10F 77/211; H10F 77/247; H10F 77/251; H10F 77/488

(57) ABSTRACT

The present invention relates to a solar cell (10) comprising a substrate (100) made of a transparent material and intended to be exposed to light radiation, a first electrode (110) formed on the substrate (100), and a unit solar cell (130) arranged between this first electrode (110) and a second electrode (120), the first and second electrodes (110, 120) being made of an electrically conductive and transparent material, the unit solar cell (130) being adapted to absorb light radiation and to generate an electric current therefrom at the terminals of said first and second electrodes (110, 120), the second electrode (120) and the unit solar cell (130) being perforated so as to allow light radiation to pass through said solar cell (10).

### TECHNICAL FIELD OF THE INVENTION

The invention relates to the field of solar cells for supplying electrical energy to electronic devices.

More particularly, the invention relates to an electronic device comprising a solar cell intended in particular to supply electrical energy to, for example, motor means or display means of a horological movement.

### TECHNOLOGICAL BACKGROUND

In certain applications, such as in the horology field, aesthetics are a critical requirement. This has led to the development of so-called “semi-transparent” solar cells, intended to be hidden from view.

This type of solar cell consists, as described in document FR2681189, of a unit solar cell arranged between a first electrode made of a transparent material and arranged on a transparent substrate, and a second electrode made of an opaque metallic material.

The solar cell has trenches and perforations extending through the second electrode and the unit solar cell, and allowing part of the incident light to pass through the solar cell. These trenches and perforations are dimensioned and distributed so that they create transparency in the solar cell for a user looking at it with the naked eye.

Naturally, the larger the surface area of the solar cell covered by the holes and/or trenches, the greater the transparency of the solar cell and the lower its electrical efficiency. Conversely, the smaller the surface area, the lower the transparency of the solar cell and the higher its electrical efficiency.

The need for the solar cell to be aesthetically pleasing thus comes at the expense of said cell's electrical efficiency, so a compromise must be found between the cell's level of transparency and its electrical efficiency.

There is thus a need to increase the electrical efficiency of semi-transparent solar cells without compromising transparency and/or aesthetics.

### SUMMARY OF THE INVENTION

The invention resolves the aforementioned drawbacks by providing an electronic device comprising a solar cell designed to meet the aesthetic requirements of the electronic device in which it is installed, for example a timepiece, while providing a sufficient level of electrical energy to power it, i.e. with high efficiency.

To this end, the present invention relates to an electronic device comprising a solar cell comprising a substrate made of a transparent material intended to be exposed to light radiation, a first electrode formed on the substrate, and a unit solar cell arranged between this first electrode and a second electrode.

The first and second electrodes are made of an electrically conductive and transparent material.

The unit solar cell is adapted to absorb light radiation, i.e. light radiation transmitted through the substrate, and to generate an electrical voltage therefrom at the terminals of said first and second electrodes. The second electrode and the unit solar cell are perforated by cavities in said solar cell so as to allow light radiation to pass through said solar cell.

The electronic device further comprises a reflecting element configured to reflect at least part of said light radiation and being arranged so that the unit solar cell is exposed to the reflected part of the light radiation.

Thus, the unit solar cell can absorb the light radiation transmitted through the substrate, as well as the reflected light radiation as the second electrode is transparent.

Thanks to the invention, the unit solar cell is thus capable of absorbing a greater quantity of light rays than those used in the prior art, resulting in a substantial improvement in its efficiency.

In particular embodiments, the invention can further include one or more of the following features, which must be considered singly or according to any combination technically possible.

In particular embodiments, the first electrode is perforated by the cavities of said solar cell.

In particular embodiments, the unit solar cell consists of three superimposed layers made of amorphous silicon and forming a PIN diode.

In particular embodiments, the substrate is made of glass, sapphire or polymer.

In particular embodiments, the first and second electrodes are made of transparent conductive oxides, such as zinc oxide or indium tin oxide.

In particular embodiments, the second electrode and the unit solar cell are perforated by cavities. Advantageously, the cavities can have a hexagonal cross-section.

The cross-sections of the cavities can alternatively have a regular or irregular shape of any kind, with simple or complex geometries to create a paving on the first electrode.

In particular embodiments, the solar cell comprises a protective coating made of a transparent material covering the first and second electrodes and the unit solar cell. For example, the protective coating is made of parylene, polyimide, nitrides or oxides.

In particular embodiments, the unit solar cell has a through-hole so as to bring the first electrode to the second electrode so as to allow connectivity between the two terminals.

The present invention further relates to a timepiece formed by an electronic device as previously described comprising a case comprising a middle, a crystal and a back defining an internal volume in which is housed a horological movement supplied with electrical energy by the solar cell, and optionally a dial, the reflecting element being formed by said dial or said horological movement.

The timepiece further comprises a solar cell as described above, arranged to supply electrical energy to the horological movement, the dial being interposed between said solar cell and the horological movement.

More particularly, the solar cell is interposed between the crystal and the horological movement, or is interposed between the crystal and the dial when the latter is included in the timepiece.

In particular embodiments of the invention, the solar cell is fastened to the crystal so that the substrate bears thereagainst, inside the case, with the second electrode facing the internal volume.

In particular embodiments of the invention, the crystal is formed by the substrate, with the solar cell being arranged so that the second electrode faces the internal volume.

In particular embodiments of the invention, the solar cell is fastened to the dial so that the substrate bears thereagainst, with the second electrode facing the crystal.

In particular embodiments of the invention, the dial is formed by the substrate, with the solar cell being arranged so that the second electrode faces the crystal.

Yet another aspect of the invention relates to a method for manufacturing a solar cell, for example in accordance with that described above, comprising the following successive steps of:
depositing, on a transparent substrate, a first electrode in the form of a transparent electrically conductive layer,
depositing, on the first electrode, a unit solar cell adapted to absorb light radiation and to generate an electric current therefrom,
patterning the unit solar cell over a predefined area,
depositing, on the unit solar cell and on the predefined area, a second electrode in the form of a transparent electrically conductive layer,
patterning the second electrode and the unit solar cell over a predefined area so as to electrically isolate the first and second electrodes.

The step of patterning the solar cell allows cavities to be generated in the solar cell.

In particular implementations of the invention, the first electrode is perforated during the step of patterning the second electrode and the unit solar cell.

In particular implementations of the invention, the first and second electrodes and the unit solar cell are encapsulated with a transparent material forming a protective coating.

In particular implementations of the invention, the first and second electrodes are deposited by a physical vapour deposition method or by a chemical vapour deposition method.

In particular implementations of the invention, the unit solar cell is deposited by a plasma-enhanced chemical vapour deposition method.

In particular implementations of the invention, the step of patterning the second electrode and the unit solar cell is carried out in a single operation.

In particular implementations of the invention, the step of patterning the second electrode and the unit solar cell is carried out by a dry etching method.

In particular implementations of the invention, the step of patterning the second electrode and the unit solar cell is carried out by a reactive ion etching method, by a wet etching method, or by a combination of dry and wet etching methods.

### BRIEF DESCRIPTION OF THE FIGURES

Other features and advantages of the invention will become apparent from the following detailed description, which is given by way of example and is by no means limiting, with reference to the accompanying drawings in which:

FIG. 1 diagrammatically shows a cross-sectional view of a solar cell according to the invention;

FIGS. 2 to 5 diagrammatically show a cross-sectional view of the solar cell of FIG. 1 at different steps of a manufacturing method according to the invention.

### DETAILED DESCRIPTION OF THE INVENTION

The description of the invention is given in the context of an application of the invention to an electronic device formed by a timepiece, for example a watch. However, it goes without saying that the invention is not limited to this application and that it could advantageously be used with any other electronic device.

It should also be noted that the term “transparent” in this text refers to the ability of a material to let through all or part of a ray of light, in particular light visible to the naked eye.

A solar cell 10 according to a preferred embodiment of the invention is adapted to transform light radiation into an electric current in order to supply, via a supply circuit, motor means or display means of a timepiece. The power supply circuit and the motor or display means of a timepiece are well known to a person skilled in the art, and do not as such relate to the present invention. They will thus not be described in detail below and are not shown in the figures.

The timepiece comprises a case including a middle, a crystal and a back. The case defines an internal volume housing a horological movement comprising the power supply circuit and the aforementioned motor or display means, and optionally a dial. These timepiece components and their arrangement are well known to a person skilled in the art.

In a preferred example embodiment of the invention, the solar cell 10 is arranged between the crystal and the dial.

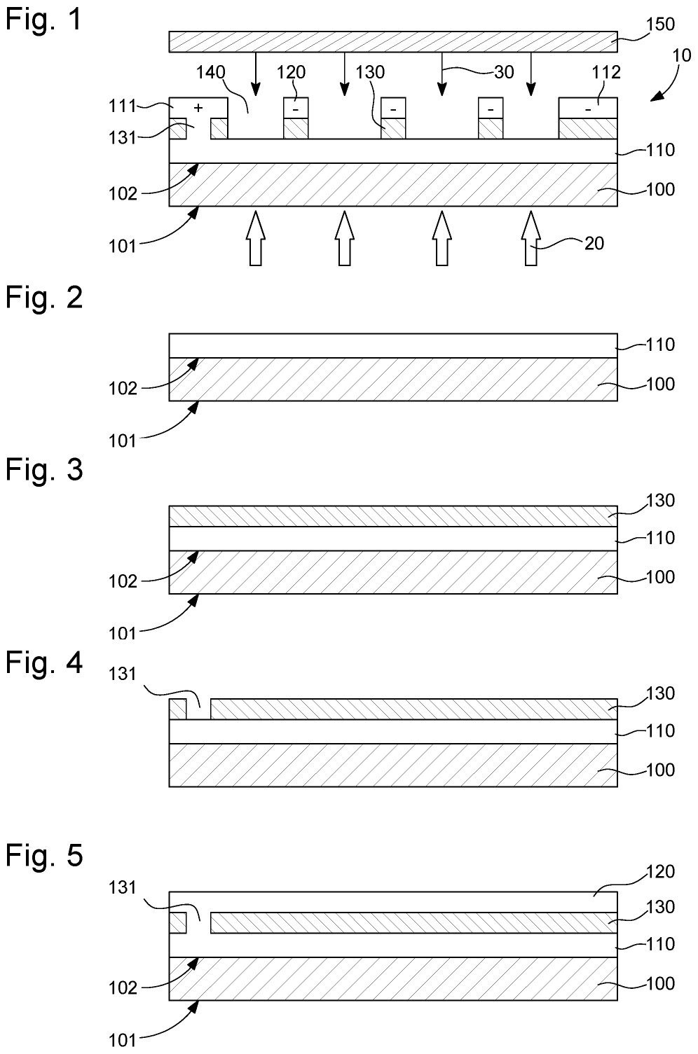

As shown in FIG. 1, the solar cell 10 comprises a substrate 100 made of a transparent material intended to be exposed to light radiation via a first face 101. In an alternative embodiment, said light radiation is incident radiation or transmitted radiation. In FIG. 1, the incident or transmitted radiation is symbolised by thick arrows 20.

This substrate 100 is made, for example, of glass, sapphire or a polymer, such as polyethylene naphthalate, also known by the acronym “PEN”, or polyethylene terephthalate, also known by the acronym “PET”. Other possibilities include polymers such as polycarbonate, also known by the acronym PC or polymethyl methacrylate acrylic, also known by the acronym PMMA.

The substrate 100 can be fastened so that its first face 101 is arranged against the crystal, for example by adhesive bonding or by mechanical or physical fastening means, such as ionic bonding or pulsed electric-current bonding, on its periphery. The light radiation to which the first face 101 of the substrate 100 is subjected is thus radiation transmitted through the crystal.

Alternatively, the substrate 100 can constitute the crystal of the timepiece. The light radiation to which the first face 101 of said substrate 100 is subjected is thus incident radiation.

The substrate 100 can conceivably have, in particular in this case, an anti-reflective treatment on its first surface 101 in order to maximise the quantity of light radiation received through said substrate.

The solar cell 10 further comprises a first electrode 110 formed on all or part of a surface of a second face 102 of the substrate 100. This first electrode 110 is directly exposed to light radiation transmitted through the substrate 100, resulting from radiation passing through said substrate 100.

As shown in FIG. 1, a unit solar cell 130 is arranged between this first electrode 110 and a second electrode 120.

In this alternative embodiment of the invention, the second electrode 120 is intended to face the internal volume of the case.

The first and second electrodes 110 and 120 are connected to each other through the unit solar cell 130, and are made of an electrically conductive and transparent material, such as a transparent conductive oxide, also known by the acronym “TCO”. Such a transparent conductive oxide can be zinc oxide or indium tin oxide.

The unit solar cell 130 is adapted to absorb light radiation and to generate an electric current therefrom at terminals 111 and 112 of the first and second electrodes 110 and 120.

As can be seen in FIG. 1, the unit solar cell 130 has a through-hole 131 which allows the first electrode 110 to be brought to the second electrode 120 so as to allow simple connectivity between the two terminals 111 and 112 on the same face of the substrate 100, in this case on the second face 102.

The terminals 111 and 112 are covered with a layer of electrically conductive material, for example silver paste or another metallic material, in order to improve their electrical conductivity. This layer of electrically conductive material is deposited by any printing or material deposition technique known per se to a person skilled in the art, for example by a physical vapour deposition method.

More particularly, the unit solar cell 130 consists of a plurality of superimposed thin layers (not shown), for example three in number, made of amorphous silicon.

These three thin layers form a PIN diode, with one of the layers forming an intrinsic region sandwiched between a p region and an n region. The design of such a PIN diode is known to a person skilled in the art, and will thus not be described in greater detail in the remainder of the text.

As shown in FIG. 1, the second electrode 120 and the unit solar cell 130 are perforated to allow transmitted radiation to pass through said solar cell 10.

More specifically, the solar cell 10 comprises cavities 140 passing through the second electrode 120 and the unit solar cell 130. These cavities 140 are blind in the sense that they do not extend into the substrate 100. Each cavity 140 thus forms coaxial through-holes in the second electrode 120 and the solar cell 130, as shown in FIG. 1.

Thus, the transmitted radiation can pass through the solar cell 10, with the substrate 100 and the first electrode 110 being transparent, and part of this transmitted radiation can be reflected by a reflecting element 150 of the electronic device.

In the preferred application of the present invention, such an element is constituted by the dial of the timepiece or by the horological movement.

In an alternative embodiment, the first electrode 110 can further be perforated to maximise the transparency of the solar cell 10. The cavities 140 thus pass through the first and second electrodes 110 and 120 and the unit solar cell 130. Each cavity 140 thus forms coaxial through-holes in the first and second electrodes 110 and 120, and the solar cell 130.

The dial or horological movement is adapted to reflect part of the light radiation that has passed through the cavities 140 of the solar cell 10, i.e. the radiation transmitted through the substrate and the first electrode 110. For example, the dial or horological movement is adapted to reflect more than 50% of the light radiation it receives.

The reflected part of the light radiation is referred to as “reflected radiation” in the rest of the text, and is symbolised by thin arrows 30 in FIG. 1.

Advantageously, the unit solar cell 130 can thus absorb part of the radiation transmitted through the substrate and part of the radiation reflected by the dial or by the horological movement.

As the second electrode 120 is made of a transparent material, the light-absorbing surface of the unit solar cell 130 is increased, thus increasing the efficiency of the unit solar cell 130.

Advantageously, the cavities 140 can have a hexagonal cross-section. This shape has the advantage of minimising electrical loss.

The cross-sections of the cavities 140 can alternatively have a regular or irregular shape of any kind, with simple or multiple geometries, to create a paving on the first electrode 110. By way of example, the cavities 140 can be filiform, such as grooves, or polygonal in shape, such as triangular, square, in the shape of letters, logos, etc.

The solar cell 10 can comprise a protective coating (not shown in the figures) made of a transparent material, encapsulating the first and second electrodes 110 and 120, as well as the unit solar cell 130. This protective coating protects the solar cell 10 from any external attack or pollution.

Such a protective coating can be made of parylene, polyimide, nitrides or oxides.

In another alternative embodiment of the invention, the substrate 100 can be fastened so that its first face 101 is arranged against the dial or against the horological movement, for example by adhesive bonding or by mechanical fastening means on its periphery.

Alternatively, the substrate 100 can form the dial. The second electrode 120 is thus intended to face the crystal.

The unit solar cell 130 can thus absorb part of the radiation transmitted through the crystal and part of the radiation reflected by the horological movement.

The present invention further relates to a method for manufacturing a solar cell, for example in accordance with the solar cell 10 described above.

The manufacturing method comprises the following successive steps, shown chronologically in FIGS. 2 to 5 and FIG. 1 respectively, of:
depositing, on a transparent substrate 100, a first electrode 110 in the form of a transparent electrically conductive layer,
depositing, on the first electrode 110, a unit solar cell 130 adapted to absorb light radiation and to generate an electric current therefrom,
patterning the unit solar cell 130 over a predefined area, so as to form a through-hole 131,
depositing, on the unit solar cell 130 and on the predefined area so as to fill the through-hole 131, a second electrode 120 in the form of a transparent electrically conductive layer,
patterning the second electrode 120 and the unit solar cell 130 over a predefined area so as to electrically isolate the first and second electrodes 110 and 120.

The patterning step allows a plurality of cavities 140 to be formed in the solar cell 10.

The first electrode can further be patterned during this patterning step.

Advantageously, several solar cells can be formed in parallel or in series by implementing the method according to the present invention.

In a final step not shown in the figures, the first and second electrodes 110 and 120 and the unit solar cell 130 can be encapsulated with a transparent material forming a protective coating.

In particular, this final step can be carried out using material deposition methods which vary according to the material chosen to form the protective coating. For example, the final step can be carried out by a chemical vapour deposition method if the material of the protective coating is parylene, by centrifugal coating if the material of the protective coating is polyimide, or by plasma-enhanced chemical vapour deposition (CVD or ALD) if the material chosen to form the protective coating is an oxide. The protective coating can also be deposited by a physical vapour deposition method, by evaporation or by cathodic sputtering, for example in the case where the protective coating is made of nitrides.

The step of depositing the first and second electrodes 110 and 120 can be carried out by a physical vapour deposition method or by a chemical vapour deposition method.

Moreover, the unit solar cell 130 can be deposited by a plasma-enhanced chemical vapour deposition method.

Advantageously, the step of patterning the second electrode 120 and the unit solar cell 130 can be carried out in a single operation. This arrangement is made possible by the particular design of the solar cell 10 according to the invention.

The patterning step can be carried out by a dry etching method, for example a reactive ion etching method, by a wet etching method, or by a combination of dry and wet etching methods.

1. An electronic device comprising a solar cell (10) comprising:
a substrate (100) made of a transparent material intended to be exposed to light radiation,
a first electrode (110) formed on the substrate (100), and
a unit solar cell (130) arranged between this first electrode (110) and a second electrode (120),
wherein the first and second electrodes (110, 120) are made of a transparent electrically conductive material, the unit solar cell (130) being adapted to absorb light radiation and to generate an electric current therefrom at terminals (111, 112) of said first and second electrodes (110, 120), the second electrode (120) and the unit solar cell (130) being perforated by cavities (140) of said solar cell (10), so as to allow light radiation to pass through said solar cell (10), and
wherein the electronic device further comprises a reflecting element (150) configured to reflect at least part of said light radiation and being arranged so that the unit solar cell (130) is exposed to the reflected part of the light radiation.

2. The electronic device according to claim 1, wherein the first electrode (110) is perforated by the cavities (140).

3. The electronic device according to claim 1, wherein the unit solar cell (130) consists of three superimposed layers made of amorphous silicon and forming a PIN diode.

4. The electronic device according to claim 1, wherein the substrate (100) is made of glass, sapphire or polymer.

5. The electronic device according to claim 1, wherein the first and second electrodes (110, 120) are made of transparent conductive oxides.

6. The electronic device according to claim 5, wherein the first and second electrodes (110, 120) are made of zinc oxide or indium tin oxide.

7. The electronic device according to claim 1, wherein the cavities (140) have a hexagonal cross-section.

8. The electronic device according to claim 1, comprising a coating made of a transparent material and covering the first and second electrodes (110, 120) and the unit solar cell (130).

9. The electronic device according to claim 8, wherein the coating is made of parylene, polyimide, nitride or oxide.

10. The electronic device according to claim 1, wherein the unit solar cell (130) has a through-hole (131) so as to bring the first electrode (110) to the second electrode (120) so as to allow connectivity between the two terminals (111, 112).

11. A timepiece comprising the electronic device according to claim 1, and a case comprising a middle, a crystal and a back defining an internal volume in which is housed a horological movement supplied with electrical energy by the solar cell (10), the reflecting element (150) being formed by a dial or by said horological movement.

12. The timepiece according to claim 11, wherein the solar cell (10) is fastened to the crystal so that the substrate (100) bears thereagainst, with the second electrode (120) facing the internal volume of the case.

13. The timepiece according to claim 11, wherein the crystal is formed by the substrate (100), with the solar cell (10) being arranged so that the second electrode (120) faces the internal volume.

14. The timepiece according to claim 11, wherein the solar cell (10) is fastened to a dial or to the horological movement, so that the substrate (100) bears thereagainst, with the second electrode (120) facing the crystal.

15. The timepiece according to claim 11, comprising a dial formed by the substrate (100), with the solar cell (10) being arranged so that the second electrode (120) faces the crystal.

16. A method for manufacturing a solar cell (10), comprising the following successive steps of:
depositing, on a transparent substrate (100), a first electrode (110) in the form of a transparent electrically conductive layer,
depositing, on the first electrode (110), a unit solar cell (130) adapted to absorb light radiation and to generate an electric current therefrom,
patterning the unit solar cell (130) over a predefined area,
depositing, on the unit solar cell (130) and on the predefined area, a second electrode (120) in the form of a transparent electrically conductive layer, and
patterning the second electrode (120) and the unit solar cell (130) over a predefined area so as to electrically isolate the first and second electrodes (110, 120).

17. The manufacturing method according to claim 16, wherein the first electrode (110) is perforated during the step of patterning the second electrode (120) and the unit solar cell (130).

18. The manufacturing method according to claim 16, wherein the first and second electrodes (110, 120) and the unit solar cell (130) are encapsulated with a transparent material forming a protective coating.

19. The manufacturing method according to claim 16, wherein the deposition of the first and second electrodes (110, 120) is performed by a physical vapour deposition method or by a chemical vapour deposition method.

20. The manufacturing method according to claim 16, wherein the unit solar cell (130) is deposited by a plasma-enhanced chemical vapour deposition method.

21. The manufacturing method according to claim 16, wherein the step of patterning the second electrode (120) and the unit solar cell (130) is performed in a single operation.

22. The manufacturing method according to claim 21, wherein the step of patterning the second electrode (120) and the unit solar cell (130) is performed by a dry etching method.

23. The manufacturing method according to claim 22, wherein the step of patterning the second electrode (120) and the unit solar cell (130) is performed by a reactive ion etching method, by a wet etching method, or by a combination of dry and wet etching methods.
